(19) United States
(12) Patent Application Publication
(10) Pub. No.: US 2024/0179870 A1
(43) Pub. Date: May 30, 2024

(54) FLUID GUIDING DEVICE FOR GUIDING A FLUID IN A CHARGING STATION AND CHARGING STATION COMPRISING SUCH A FLUID GUIDING DEVICE

(71) Applicant: ads-tec Energy GmbH, Nürtingen (DE)

(72) Inventors: Andreas GREIF, Weilheim (DE); Roman MOLCHANOV, Neckartenzlingen (DE); Simon BAREIß, Rudersberg (DE)

(21) Appl. No.: 18/511,212

(22) Filed: Nov. 16, 2023

(30) Foreign Application Priority Data
Nov. 24, 2022 (DE) 102022131170.8

(51) Int. Cl. H05K 7/20; B60L 53/302; H02J 7/00

(52) U.S. Cl. CPC H05K 7/20272; B60L 53/302; H02J 7/0042; H05K 7/20927

(57) ABSTRACT

The invention relates to a fluid guiding device for guiding a fluid in a charging station, whereby
the fluid guiding device has a longitudinal channel, which extends in a longitudinal direction, whereby
at least two first fluid connections, which lead away transversely to the longitudinal direction, are arranged on the longitudinal channel along the longitudinal direction, whereby
at least one second fluid connection is arranged on a first end of the longitudinal channel, whereby
the longitudinal channel is closed on a front side on a second end located opposite the first end, whereby
the longitudinal channel connects the at least two first fluid connections fluidically in parallel to the at least one second fluid connection, as well as
   a charging station comprising at least two such fluid guiding devices.

### CROSS REFERENCE TO RELATED APPLICATIONS

This application claims priority to and the benefit of German Patent Application No. 102022131170.8 filed on Nov. 24, 2022, the entire contents of which are incorporated herein by reference.

The invention relates to a fluid guiding device for guiding a fluid in a charging station and a charging station comprising at least one electronic module and at least one such fluid guiding device

Advancements in the development of battery storages provide for a higher electrical capacity with in particular consistent installation space of the battery storage. As a result, battery storages with a higher electrical capacity can be installed in electric vehicles. The users of electric vehicles usually expect a quick charging of the battery storage, in order to be able to continue driving promptly and are thus not necessarily willing to stay longer at the charging station due to a battery storage, which has a larger electrical capacity.

As a result, it is necessary that a charging power for charging the battery storage is increased. An increase of the charging power is in particular accompanied by an increase of the charging current and/or of the charging voltage. The heat created thereby in the charging station, in particular due to electronic modules, in particular due to the power electronics, is usually dissipated by a climate control device of the charging station. A fluid cooled by the climate control device is thereby usually conveyed through a fluid conveying device—in particular to cool the power electronics—and is distributed in the charging station by means of a fluid guiding device. Such a fluid guiding device usually has a complex flow path, so that the fluid can be conveyed to all electronic modules, which are to be cooled. Due to the complex flow path, such a fluid guiding device usually occupies a large amount of installation space within the charging station.

The fluid is usually conveyed to a cooling circuit of the electronic module by means of the fluid guiding device. If such an electronic module fails, the cooling circuit thereof has to be separated from the fluid guiding device and has to be removed from the charging station. This can in particular result in a partial leaking of the fluid contained in the cooling circuit of the electronic module, so that said fluid unintentionally reaches into the charging station and may damage electronic components there. When reinserting the module into the charging station, the cooling circuit of the electronic module has to be connected in terms of flow, i.e. fluidically, and in a leakage-free manner to the fluid device again. In particular due to manufacturing inaccuracies or an inaccurate positioning of the connections, it is not always easily possible to establish a connection in terms of flow between the cooling circuit of the electronic module and the fluid guiding device.

The invention is thus based on the object of creating a fluid guiding device for guiding a fluid in a charging station and a charging station comprising at least one electronic module and at least one such fluid guiding device, whereby the mentioned disadvantages are reduced, preferably do not occur.

The object is solved in that the present technical teaching is provided, in particular the teaching of the independent claims as well as of the preferred embodiments disclosed in the dependent claims and the description.

The object is in particular solved in that a fluid guiding device for guiding a fluid in a charging station is created. The fluid guiding device has a longitudinal channel, which extends in a longitudinal direction, whereby at least two first fluid connections, which lead away transversely to the longitudinal direction, are arranged on the longitudinal channel along the longitudinal direction. At least one second fluid connection is arranged on a first end of the longitudinal channel. The longitudinal channel is closed on the front side on a second end located opposite the first end. The longitudinal channel connects the at least two first fluid connections in terms of flow in parallel to the at least one second fluid connection. A particularly compact fluid guiding device, which can in particular be arranged in a charging station in a space-saving manner, is advantageously provided in this way. Due to the formation of the fluid guiding device as longitudinal channel, it is in particular possible to convey the fluid within the fluid guiding device in a space-saving manner to just in front of an electronic module of the charging station. Unnecessary connecting points are thus advantageously avoided, whereby the risk of a leakage can be reduced, preferably avoided.

The fluid is in particular a climate control fluid, in particular a cooling fluid, in particular water, in particular a water-glycol mixture.

In one embodiment, the longitudinal channel, which extends in the longitudinal direction, in particular has a profile with a rectangular cross section, with its longer side being oriented transversely to the longitudinal direction or is formed thereby. The edges, which are oriented parallel to the longitudinal direction—the corners of the rectangular profile—of the longitudinal channel are in particular rounded.

In another embodiment, the longitudinal channel, which extends in a longitudinal direction, in particular has a profile with a circular or elliptical cross section or is formed thereby. If the profile is elliptical, its main axis is preferably oriented transversely to the longitudinal direction.

The longitudinal channel is in particular formed as lance or in a lance-shaped manner.

In electrical engineering, any, in particular stationary or mobile device or electrical installation, which serves the purpose of supplying energy to mobile accumulator-operated equipment, machines, or motor vehicles, by means of a simple setting or plugging in, without inevitably having to remove the energy storage—for instance the traction battery of an electric vehicle—is referred to as charging station. Charging stations for electric vehicles are sometimes also referred to as “electricity charging stations” and can comprise several charging points. In particular direct current quick charging systems (high performance charging systems or high power charging systems, HPC systems) such as the so-called combined charging system (CCS), which is common in Europe, are known here. During the generic direct current charging, direct current from the charging station is fed directly into the battery of the vehicle and is, for this purpose, provided to, e.g., solar charging stations by means of a powerful rectifier, preferably of the charging station, from the power supply or by means of large buffer accumulators. A battery management system, which communicates directly or indirectly with the charging station, in order to adapt the current and voltage or to end the process when reaching a predetermined capacity limit, is located in the vehicle. Power electronics are thereby typically located in the charging station. Due to the fact that the DC connections of the charging station are connected directly—without detour via an AC/DC converter of the vehicle—to corresponding connections of the traction battery, high charging currents can be transferred with little loss, which provides for short charging times.

In one embodiment, the charging station is formed as a charging column. The charging station in particular has at least one charging point, in particular exactly one charging point or exactly two charging points.

The charging station is in particular formed as quick charging station. In one embodiment, the charging station is formed as battery-supported charging station, in particular as battery-supported quick charging station.

According to a further development of the invention, it is provided that the longitudinal channel is formed to be deformable. Advantageously, manufacturing inaccuracies and/or an inaccurate positioning of connections, which correspond to the longitudinal channel, of a charging station or also of the fluid connections themselves can be compensated in this way. It is in particular possible thereby to arrange an electronic module in the charging station particularly easily and to establish a connection in terms of flow.

In another embodiment, the longitudinal channel is formed to be rigid. It is then possible particularly easily to insert the longitudinal channel into a charging station—in particular from one side or front side.

In the context of the present technical teaching, the fact that the longitudinal channel is formed to be deformable means in particular that a length of the longitudinal channel can be changed, in particular that the longitudinal channel can be compressed and/or expanded along the longitudinal direction. Alternatively or additionally, the longitudinal channel can be curved. The longitudinal channel is in particular deformable repeatedly, in particular in a destruction-free manner. The longitudinal channel is in particular deformable in that the longitudinal channel has a deformable material and/or a shape, which is suitable for the deformation. In one embodiment, the longitudinal channel has a corrugated pipe or is formed as corrugated pipe.

According to a further development of the invention, it is provided that the at least two first fluid connections are releasably fastened to the longitudinal channel, in particular so as to be capable of being unscrewed and/or removed. It is particularly easily possible in this way to exchange a defective fluid connection or to replace it with a fluid connection with a different connection diameter, in particular by means of screwing on or attaching.

According to a further development of the invention, it is provided that the longitudinal channel and at least one first fluid connection, selected from the at least two first fluid connections, form a mounting recess, in particular a groove, whereby the mounting recess is configured to mount the fluid guiding device in the charging station, in particular optionally in a displaceable manner or non-displaceable manner relative to a housing of the charging station. Advantageously, a particularly compact construction of the fluid guiding device is realized in this way. The fluid guiding device in particular forgoes additional fastening elements, by means of which the fluid guiding device can be fastened to a charging station because the mounting recess, as fastening element, is formed by the fluid guiding device itself.

A fluid guiding assembly, which has a first fluid guiding device comprising a rigid longitudinal channel, and a second fluid guiding device—which is in particular arranged parallel to the first fluid guiding device—comprising a deformable longitudinal channel, also belongs to the invention.

The object is also solved in that a charging station comprising at least one electronic module and at least two fluid guiding devices according to the invention or fluid guiding devices according to one or several of the above-described embodiments is created. The charging station has a first fluid guiding device of the at least two fluid guiding devices as a fluid supply device. As the at least two first fluid connections, the fluid supply device has at least two fluid exit connections. One fluid exit connection of the at least two fluid exit connections is releasably connected to a fluid circuit entrance connection, in particular cooling circuit entrance connection, of the at least one electronic module, in particular of a power electronics. The charging station has a second fluid guiding device of the at least two fluid guiding devices as a fluid discharge device. As the at least two first fluid connections, the fluid discharge device has at least two fluid entrance connections. One fluid entrance connection of the at least two fluid entrance connections is releasably connected to a fluid circuit exit connection, in particular cooling circuit exit connection, of the at least one electronic module, in particular of the power electronics. A fluid guiding device, selected from the fluid discharge device and the fluid supply device, has a deformable longitudinal channel. In particular the advantages, which have already been described in connection with the fluid guiding device result in connection with the charging station.

In one embodiment, the other fluid guiding device, selected from the fluid supply device and the fluid discharge device, has a rigid longitudinal channel. The charging station in particular has a fluid guiding assembly according to the invention or a fluid guiding assembly according to one or several of the above-described embodiments.

A further fluid exit connection of the at least two fluid exit connections is in particular releasably connected to a fluid circuit entrance connection, in particular cooling circuit entrance connection, of a further electronic module of the charging station, in particular of a further power electronics.

A further fluid entrance connection of the at least two fluid entrance connections is in particular releasably connected to a fluid circuit exit connection, in particular cooling circuit exit connection, of the further electronic module, in particular of the further power electronics.

The fluid in particular flows through the fluid supply device and from there through the respective fluid exit connection into the assigned fluid circuit entrance connection, from there flows through the assigned electronic module, in order to cool it, leaves the latter, in turn through the assigned fluid circuit exit connection, whereby it enters through the assigned fluid entrance connection into the fluid discharge device and continues to flow through the latter. Two separate electronic modules or, alternatively, also one larger electronic module can in particular be supplied with the fluid in this way with the help of the respective two first fluid connections of the fluid guiding devices.

According to a further development of the invention, it is provided that at least one fluid connection, in particular each of the fluid connections, selected from the at least two fluid exit connections and the at least two fluid entrance connections, has a plug receptacle. A fluid circuit connection assigned to the fluid connection, selected from the fluid circuit entrance connection and the fluid circuit exit connection, has a plug. The plug can be connected in terms of flow to the plug receptacle, in that the plug is releasably inserted into the plug receptacle. The plug is in particular formed in such a way that it is closed in a fluid-tight manner when the plug is released from the plug receptacle. Advantageously, a connection in terms of flow between the fluid connection and the fluid circuit connection is established and disconnected particularly easily in this way. It is in particular possible to disconnect and to reestablish a connection in terms of flow in a drip-free manner. In particular the risk of a leakage is thus reduced, preferably avoided. The electronic module is in particular not damaged by a leaked fluid.

The plug receptacle in particular has a cup shape or is formed in a cup-shaped manner.

The plug is in particular configured to establish a connection in terms of flow between the fluid connection and the assigned fluid circuit connection when being inserted, in particular when being plugged into, in particular when being pushed into the plug receptacle. The plug is configured in such a way that the connection in terms of flow is disconnected again when releasing the plug.

According to a further development of the invention, it is provided that the mounting recess of a fixed fluid guiding device, selected from the fluid supply device and the fluid discharge device, cooperates with a first aperture of a wall of the charging station, so that a fixed fluid connection of the at least two first fluid connections of the fixed fluid guiding device is fixed in the charging station, that is, in particular fastened in a displacement-free or rigid manner, in particular so as to be clamped. A first fluid path is formed from the longitudinal channel of the fixed fluid guiding device to the fixed fluid connection, whereby the first fluid path is guided through the first aperture. The two first fluid connections of the fixed fluid guiding device are in particular fixed in this way. The mounting recess of a displaceable fluid guiding device, selected from the fluid supply device and the fluid discharge device, cooperates with a second aperture of the wall of the charging station, so that a displaceable fluid connection of the at least two first fluid connections of the displaceable fluid guiding device, is displaceably mounted in the charging station, in particular so as to float. A second fluid path is formed from the longitudinal channel of the displaceable fluid guiding device to the displaceable fluid connection, whereby the second fluid path is guided through the second aperture. The two first fluid connections of the displaceable fluid guiding device are in particular displaceably mounted in this way, in particular so as to float. Alternatively, one of the first fluid connections of the displaceable fluid guiding device is displaceably fastened and the other one is rigidly fastened. Advantageously, the fixed fluid guiding device is in particular fastened to the charging station by means of a type of fixed bearing and the displaceable fluid guiding device is fastened to the charging station by means of a type of loose bearing. Due to the displaceable design of the displaceable fluid guiding device, a compensation of manufacturing inaccuracies and of an inaccurate positioning of the connections is in particular possible.

In the context of the present technical teaching, the fact that a displaceable fluid connection of the at least two first fluid connections of the displaceable fluid guiding device is displaceably mounted in the charging station means in particular that the displaceable fluid connection is displaceably mounted, in particular so as to float, in a plane, which is arranged parallel to the wall. The displaceable fluid connection is in particular displaceable relative to the wall of the charging station. The displaceable fluid connection is in particular displaceable relative to a further displaceable or fixed fluid connection of the at least two first fluid connections of the displaceable fluid guiding device. The displaceable fluid connection of the displaceable fluid guiding device is in particular displaceable relative to a fixed fluid connection of the fastened fluid guiding device.

According to a further development of the invention, it is provided that a sliding element, in particular a sliding ring, in particular a plastic ring, is arranged between the displaceable fluid connection of the displaceable fluid guiding device and the wall. The displacement of the displaceable fluid guiding device is possible particularly easily in this way.

According to a further development of the invention, it is provided that the charging station has an electronics region and a fluid region. The wall is arranged between the electronics region and the fluid region. The electronic module, in particular the power electronics, is arranged in the electronics region. The fluid supply device and the fluid discharge device are arranged in the fluid region. The charging station can be operated particularly safely and reliably in this way because in particular a spatial separation between the electronics region and the fluid region is realized. A condensate formation on the fluid guiding device in particular does not occur in the electronics region, because said fluid guiding device is arranged in the spatially separated fluid region.

The fluid region is in particular arranged geodetically below the electronics region. Fluid, which may escape from the fluid region, cannot flow into the electronics region in this way. Alternatively or additionally, the wall, which separates or limits the fluid region from the electronics region, is aligned horizontally. The electronics region is in particular arranged above the horizontal wall, and the fluid region is arranged below the horizontal wall.

According to a further development of the invention, it is provided that the charging station has a heat storage device and a climate control device. As the at least one second fluid connection, the fluid supply device has two second fluid connections, namely a heat storage device entrance as a first second fluid connection and a climate control device exit as a second second fluid connection. The heat storage device entrance is connected in terms of flow to the heat storage device, and the climate control device exit is connected in terms of flow to an inlet of the climate control device. As the at least one second fluid connection, the fluid discharge device has two second fluid connections, namely a heat storage device exit as a first second fluid connection and an climate control device entrance as a second second fluid connection. The heat storage device exit is connected in terms of flow to the heat storage device, and the climate control device entrance is connected in terms of flow to an outlet of the climate control device. Advantageously, a particularly simple and installation space-saving flow path is realized in the charging station in this way. Advantageously, additional lines and valves are forgone.

The heat storage device is in particular a container or a tank for the fluid. The heat storage device is in particular insulated, in particular thermally insulated.

According to a further development of the invention, it is provided that the two fluid exit connections and the climate control device exit are adapted to one another in such a way that a predetermined distribution of the respective fluid flows, which pass through, is attained during the operation of the charging station, which is also referred to as hydraulic balancing. Advantageously, additional components for carrying out the hydraulic balancing can be forgone in this way. An additional balancing module for carrying out the hydraulic balancing can further also be forgone.

Alternatively or additionally, it is provided that the two fluid entrance connections and the climate control device entrance are adapted to one another in such a way that a predetermined distribution of the respective fluid flows, which pass through the two fluid exit connections and the climate control device exit, is attained during the operation of the charging station.

According to a further development of the invention, it is provided that the charging station has a fluid conveying device. The fluid conveying device is configured to convey a fluid of the charging station. It is thus in particular ensured that a sufficient amount of fluid is conveyed through the fluid guiding device.

The fluid conveying device in particular conveys a fluid from the heat storage device via the heat storage device entrance into the fluid supply device. The flow is in particular divided into three fluid flow portions here:

A first fluid flow portion flows in particular via the climate control device exit as well as via the inlet of the climate control device into the climate control device and is cooled there. The cooled first fluid flow portion in particular flows via the outlet of the climate control device and the climate control device entrance into the fluid discharge device.

A second fluid flow portion flows in particular from the fluid supply device via one of the fluid exit connections and the assigned fluid circuit entrance connection of the assigned electronic module into a fluid circuit of the electronic module. The second fluid flow portion in particular absorbs heat from the electronic module. The heated second fluid flow portion in particular flows via the fluid circuit exit connection of the electronic module and via one of the fluid entrance connections of the fluid discharge device into the fluid discharge device.

A third fluid flow portion flows in particular from the fluid supply device via the other fluid exit connection and the assigned fluid circuit entrance connection of the assigned electronic module into a fluid circuit of the electronic module. The third fluid flow portion in particular absorbs heat from the electronic module. The heated third fluid flow portion in particular flows via the fluid circuit exit connection of the electronic module and via the other fluid entrance connection of the fluid discharge device into the fluid discharge device.

The above-described hydraulic balancing comprises in particular a predetermined distribution between the first, the second, and the third fluid flow portion.

The first fluid flow portion in particular combines with the second and third fluid flow portion in the fluid discharge device, and the combined fluid flow flows via the heat storage device exit back into the heat storage device.

The invention will be described in more detail below on the basis of the drawing, in which:

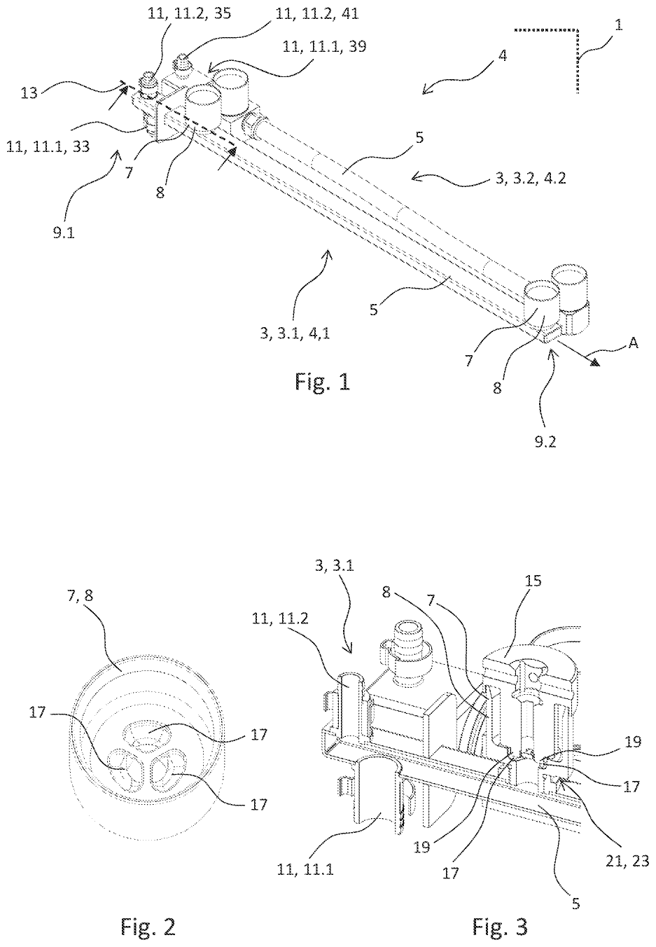

FIG. 1 shows a schematic illustration of an exemplary embodiment of a fluid guiding assembly comprising two fluid guiding devices for guiding a fluid of a charging station;

FIG. 2 shows a schematic illustration of an exemplary embodiment of a first fluid connection 7 of the fluid guiding devices according to FIG. 1 as a plug receptacle;

FIG. 3 shows a schematic, partial illustration of a sectional view of a longitudinal section of one of the fluid guiding devices according to FIG. 1;

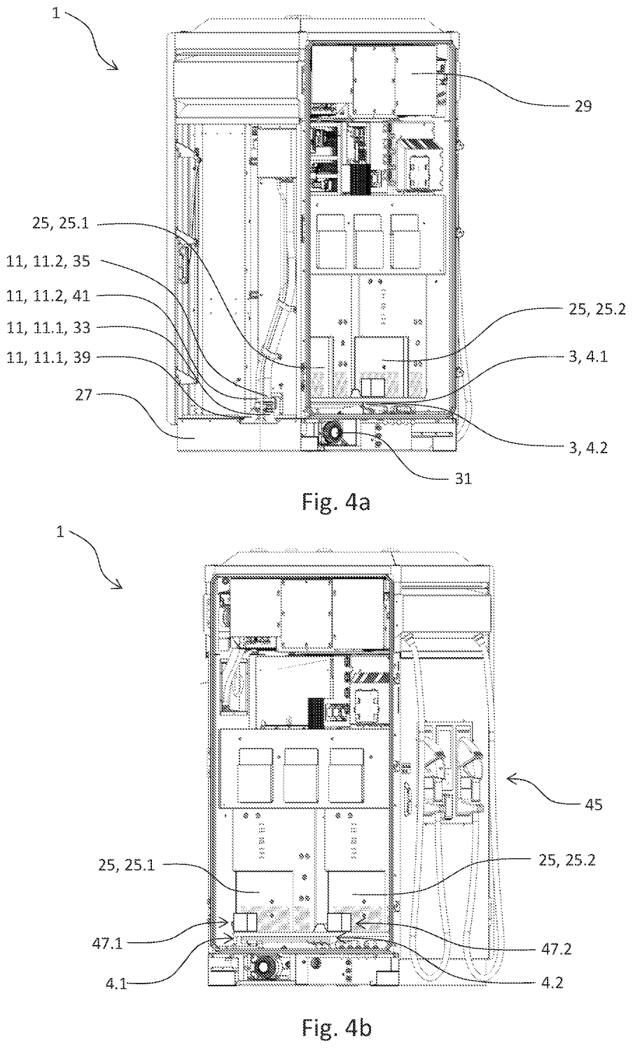

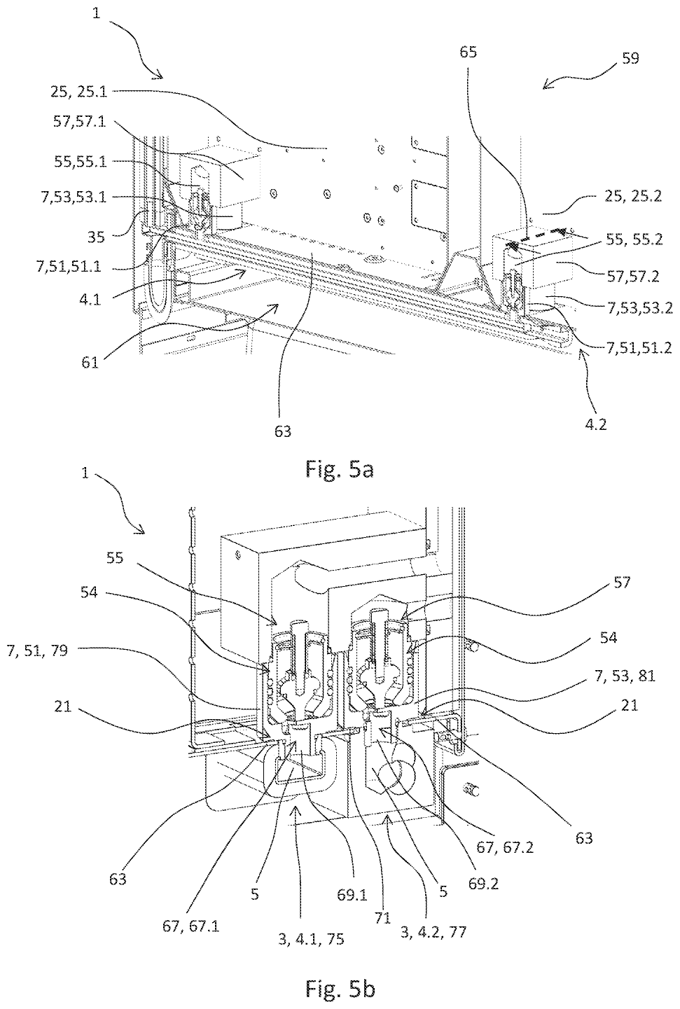

FIG. 4a shows a schematic illustration of a first view of an exemplary embodiment of a charging station comprising a fluid guiding assembly according to FIG. 1;

FIG. 4b shows a schematic illustration of a second view of the exemplary embodiment of the charging station according to FIG. 4a;

FIG. 5a shows a schematic, enlarged illustration of a sectional view of a first section of the charging station according to FIG. 4b, and

FIG. 5b shows a schematic, enlarged illustration of a sectional view of a second section of the charging station according to FIG. 5a.

FIG. 1 shows a schematic illustration of an exemplary embodiment of a fluid guiding assembly 4 with exemplary embodiments of fluid guiding devices 3 for guiding a fluid of a charging station 1.

In this exemplary embodiment, two fluid guiding devices 3, namely a first fluid guiding device 3.1 and a second fluid guiding device 3.2 are provided.

The fluid guiding devices 3 in each case have a longitudinal channel 5, which is illustrated by the arrow A, extending in the longitudinal direction, whereby at least two first fluid connections 7, which lead away transversely to the longitudinal direction, are arranged on the longitudinal channel 5 along the longitudinal direction. At least one second fluid connection 11, here two second fluid connections 11, is arranged on a first end 9.1 of the longitudinal channel 5. The longitudinal channel 5 is closed on the front side on a second end 9.2 located opposite the first end 9.1. The longitudinal channel 5 connects the at least two first fluid connections 7 in terms of flow in parallel to the at least one second fluid connection 11.

It is preferably provided—here only in the case of the second fluid guiding device 3.2—that the longitudinal channel 5 is formed to be deformable. In the case of the first fluid guiding device 3.1, the longitudinal channel 5 is formed to be rigid.

It is preferably provided that the at least two first fluid connections 7 are releasably fastened to the longitudinal channel 5, preferably so as to be capable of being unscrewed and/or removed.

The longitudinal channel 5 is preferably formed as lance or in a lance-shaped manner.

The two first fluid connections 7 are in each case preferably formed as plug receptacle 8. Such a plug receptacle 8 is shown in FIG. 2.

A longitudinal section 13 of the first fluid guiding device 3.1, which is illustrated by means of dashes, is described in FIG. 3.

FIG. 2 shows a schematic illustration of an exemplary embodiment of a first fluid connection 7, which is formed as plug receptacle 8, of the fluid guiding devices 3 according to FIG. 1.

Identical and functionally identical elements are thereby provided with the same reference numerals in all figures, so that reference is made to the preceding description in this respect.

The plug receptacle 8 can preferably be connected to the longitudinal channel 5 by screwing said plug receptacle into the longitudinal channel 5. The screwing in preferably takes place by means of a socket wrench 15 illustrated in FIG. 3. The plug receptacle 8 preferably has three recesses 17, which are in particular formed in a kidney-shaped manner and with which the socket wrench 15 engages, which has three, in particular kidney-shaped elevations 19, which correspond to the recesses 17.

FIG. 3 shows a schematic, partial illustration of a sectional view of the longitudinal section 13 of the first fluid guiding device 3.1 according to FIG. 1. The illustration and the descriptions, however, also equally apply to the second fluid guiding device 3.2.

The socket wrench 15 comprising the in particular kidney-shaped elevations 19 engages with the in particular kidney-shaped recesses 17 of the plug receptacle 8 here.

It is preferably provided that the longitudinal channel 5 and at least one first fluid connection 7 form a mounting recess 21, preferably a groove 23, whereby the mounting recess 21 is configured to mount the fluid guiding device 3 in a charging station 1, preferably optionally in a displaceable manner or non-displaceable manner relative to a housing of the charging station 1.

The two second fluid connections 11 of the first fluid guiding device 3.1, namely a first second fluid connection 11.1 and a second second fluid connection 11.2 can likewise be seen.

FIG. 4a shows a schematic illustration of a first view of an exemplary embodiment of a charging station 1, comprising the fluid guiding assembly 4 according to FIG. 1.

The charging station 1 further has at least one electronic module 25, namely a first electronic module 25.1 and a second electronic module 25.2, as well as a heat storage device 27 and a climate control device 29. The charging station 1 further has a fluid conveying device 31, which is configured to convey a fluid of the charging station 1.

The charging station 1 has a fluid guiding device 3 of the at least two fluid guiding devices 3 as a fluid supply device 4.1 and the other fluid guiding device 3 of the at least two fluid guiding devices 3 as a fluid discharge device 4.2. The fluid discharge device 4.2 is arranged behind the fluid supply device 4.1 transversely to the image plane, thus facing away from an observer. The fluid supply device 4.1 is accordingly arranged in front of the fluid discharge device 4.2 transversely to the image plane, thus facing an observer.

As the at least one second fluid connection 11, the fluid supply device 4.1 has—in particular also with reference to FIG. 1—two second fluid connections 11, namely a heat storage device entrance 33 as the first second fluid connection 11.1 and an climate control device exit 35 as the second second fluid connection 11.2. The heat storage device entrance 33 is connected in terms of flow to the heat storage device 27, and the climate control device exit 35 is connected in terms of flow to an inlet of the climate control device 29. As the at least one second fluid connection 11, the fluid discharge device 4.2 has two second fluid connections 11, namely a heat storage device exit 39, which is concealed in FIG. 1, as the first second fluid connection 11.1 and an climate control device entrance 41 as the second second fluid connection 11.2. The heat storage device exit 39 is connected in terms of flow to the heat storage device 27 and the climate control device entrance 41 is connected in terms of flow to an outlet of the climate control device 29

FIG. 4b shows a schematic illustration of a second view of the exemplary embodiment of the charging station 1 according to FIG. 4a.

The charging station 1 has two charging points, each comprising a charging plug 45 for charging a battery storage of a non-illustrated electric vehicle.

The first electronic module 25.1 is connected at a first point 47.1 to the fluid supply device 4.1 and to the fluid discharge device 4.2.

The second electronic module 25.2 is connected at a second point 47.2 to the fluid supply device 4.1 and to the fluid discharge device 4.2.

A first longitudinal section of the charging station 1, in particular of the first point 47.1 and of the second 47.2, is described in FIG. 5a.

FIG. 5a shows a schematic, enlarged illustration of a longitudinal sectional view of the charging station 1 according to FIG. 4b.

The fluid supply device 4.1 can be seen—here cut in the longitudinal direction—and the fluid discharge device 4.2.

As the at least two first fluid connections 7, the fluid supply device 4.1 has two fluid exit connections 51, namely a first fluid exit connection 51.1 and a second fluid exit connection 51.2. The first fluid exit connection 51.1 is releasably connected to a first fluid circuit entrance connection 55.1, preferably cooling circuit entrance connection, of the first electronic module 25.1, preferably a power electronics. The second fluid exit connection 51.2 is releasably connected to a second fluid circuit entrance connection 55.2, preferably cooling circuit entrance connection, of the second electronic module 25.2, preferably a power electronics.

As the two first fluid connections 7, the fluid discharge device 4.2 has two fluid entrance connections 53, namely a first fluid entrance connection 53.1 and a second fluid entrance connection 53.2. The first fluid entrance connection 53.1 is releasably connected to a first fluid circuit exit connection 57.1, preferably cooling circuit exit connection, of the first electronic module 25.1, preferably the power electronics. The fluid discharge device 4.2 preferably has a non-illustrated, deformable longitudinal channel 5 here. The second fluid entrance connection 53.2 is releasably connected to a second fluid circuit exit connection 57.2, preferably cooling circuit exit connection, of the second electronic module 25.2, preferably the power electronics.

It is preferably provided that the charging station 1 has an electronics region 59 and a fluid region 61. A wall 63 is arranged between the electronics region 59 and the fluid region 61. The two electronic modules 25, preferably the power electronics, are arranged in the electronics region 59. The fluid supply device 4.1 and the fluid discharge device 4.2 are arranged in the fluid region 61.

It is preferably provided that the two fluid exit connections 51 and the climate control device exit 35 are adapted to one another in such a way that a predetermined distribution of the respective fluid flows, which pass through, is attained during the operation of the charging station, which is also referred to as hydraulic balancing.

A second section 65, which is illustrated by means of dashes, of the charging station 1, in particular a cross section of the fluid supply device 4.1 and of the fluid discharge device 4.2, is described in FIG. 5b.

FIG. 5b shows a schematic, enlarged illustration of a sectional view of a second section 65 of the charging station 1, in particular of a cross section of the fluid supply device 4.1 and of the fluid discharge device 4.2, according to FIG. 5a.

The fluid circuit entrance connection 55 and the fluid circuit exit connection 57 in each case have a plug 54.

The plug 54 of the fluid circuit entrance connection 55 can preferably be connected in terms of flow to the fluid exit connection 51, in that the plug 54 of the fluid circuit entrance connection 55 is releasably plugged into the fluid exit connection 51.

The plug 54 of the fluid circuit exit connection 57 can preferably be connected in terms of flow to the fluid entrance connection 53, in that the plug 54 of the fluid circuit exit connection 57 is releasably plugged into the fluid entrance connection 53.

It is preferably provided that the mounting recess 21 of a fixed fluid guiding device 75—here the fluid supply device 4.1—, selected from the fluid supply device 4.1 and the fluid discharge device 4.2, cooperates with a first aperture 67.1 of the wall 63 of the charging station 1, so that a fixed fluid connection 79 of the at least two first fluid connections 7 of the fixed fluid guiding device 75, is fastened in the charging station 1, preferably fastened in a displacement-free manner, preferably so as to be clamped. A first fluid path 69.1 is formed from the longitudinal channel 5 of the fixed fluid guiding device 75 to the fixed fluid connection 79, whereby the first fluid path 69.1 is guided through the first aperture 67.1.

The mounting recess 21 of a displaceable fluid guiding device 77—here the fluid discharge device 4.2—, selected from the fluid supply device 4.1 and the fluid discharge device 4.2, cooperates with a second aperture 67.2 of the wall 63 of the charging station 1, so that a displaceable fluid connection 81 of the at least two first fluid connections 7 of the displaceable fluid guiding device 77, is displaceably mounted in the charging station 1. A second fluid path 69.2 is formed from the longitudinal channel 5 of the displaceable fluid guiding device 77 to the displaceable fluid connection 81, whereby the second fluid path 69.2 is guided through the second aperture 67.2.

It can likewise be seen that the second aperture 67.2 has a larger diameter compared to the first aperture 67.1. Whether a fluid guiding device 3 is thus arranged in a fixed or displaceable manner in the charging station 1 is preferably a function of a diameter of the respective aperture 67, whereby a diameter of the fluid supply device 4.1 and a diameter of the fluid discharge device 4.2 can be selected identically.

It is preferably provided that a sliding element 71, preferably a sliding ring, preferably a plastic ring, is arranged between the displaceable fluid connection 81 of the displaceable fluid guiding device 77 and the wall 63, preferably arranged on a geodetically upper side of the wall 63.

1. A fluid guiding device for guiding a fluid in a charging station, whereby
the fluid guiding device has a longitudinal channel, which extends in a longitudinal direction, whereby
at least two first fluid connections, which lead away transversely to the longitudinal direction, are arranged on the longitudinal channel along the longitudinal direction, whereby
at least one second fluid connection is arranged on a first end of the longitudinal channel, whereby
the longitudinal channel is closed on a front side on a second end located opposite the first end, whereby
the longitudinal channel connects the at least two first fluid connections fluidically in parallel to the at least one second fluid connection.

2. The fluid guiding device according to claim 1, whereby the longitudinal channel is configured to be deformable.

3. The fluid guiding device according to claim 1, whereby the at least two first fluid connections are releasably fastened to the longitudinal channel.

4. The fluid guiding device according to claim 1, whereby
the longitudinal channel and at least one first fluid connection, selected from the at least two first fluid connections, form a mounting recess, whereby
the mounting recess is configured to mount the fluid guiding device in the charging station.

5. A charging station comprising at least one electronic module and comprising at least two fluid guiding devices according to claim 1, whereby
the charging station has a first fluid guiding device of the at least two fluid guiding devices as a fluid supply device, whereby
as the at least two first fluid connections, the fluid supply device has at least two fluid exit connections, whereby
one fluid exit connection of the at least two fluid exit connections is releasably connected to a fluid circuit entrance connection of the at least one electronic module, whereby
the charging station has a second fluid guiding device of the at least two fluid guiding devices as a fluid discharge device, whereby
as the at least two first fluid connections, the fluid discharge device has at least two fluid entrance connections, whereby
one fluid entrance connection of the at least two fluid entrance connections is releasably connected to a fluid circuit exit connection of the at least one electronic module, whereby
one of the fluid guiding devices, selected from the fluid discharge device and the fluid supply device, has a deformable longitudinal channel.

6. The charging station according to claim 5, whereby
at least one fluid connection, selected from the at least two fluid exit connections and the at least two fluid entrance connections, has a plug receptacle, whereby
a fluid circuit connection assigned to the fluid connection, selected from the fluid circuit entrance connection and the fluid circuit exit connection, has a plug, whereby
the plug can be fluidically connected to the plug receptacle, in that the plug is releasably inserted into the plug receptacle.

7. The charging station according to claim 5, whereby
the mounting recess of a fixed fluid guiding device, selected from the fluid supply device and the fluid discharge device, cooperates with a first aperture of a wall of the charging station, so that a fixed fluid connection of the at least two first fluid connections of the fixed fluid guiding device is fixed in the charging station, whereby a first fluid path is formed from the longitudinal channel of the fixed fluid guiding device to the fixed fluid connection, whereby the first fluid path is guided through the first aperture, whereby
the mounting recess of a displaceable fluid guiding device, selected from the fluid supply device and the fluid discharge device, cooperates with a second aperture of the wall of the charging station, so that a displaceable fluid connection of the at least two first fluid connections of the displaceable fluid guiding device, is displaceably mounted in the charging station, whereby a second fluid path is formed from the longitudinal channel of the displaceable fluid guiding device to the displaceable fluid connection, whereby the second fluid path is guided through the second aperture.

8. The charging station according to claim 7, whereby a sliding element is arranged between the displaceable fluid connection of the displaceable fluid guiding device and the wall.

9. The charging station according to claim 7, whereby
the charging station has an electronics region and a fluid region, whereby
the wall is arranged between the electronics region (59) and the fluid region, whereby
the at least one electronic module is arranged in the electronics region, whereby
the fluid supply device and the fluid discharge device are arranged in the fluid region.

10. The charging station according to claim 7, comprising a heat storage device and a climate control device, whereby
as the at least one second fluid connection, the fluid supply device has two second fluid connections, namely a heat storage device entrance as a first second fluid connection and an climate control device exit as a second second fluid connection, whereby
the heat storage device entrance is fluidically connected to the heat storage device, and the climate control device exit is fluidically connected to an inlet of the climate control device, whereby
as the at least one second fluid connection, the fluid discharge device has two second fluid connections, namely a heat storage device exit as a first second fluid connection and an climate control device entrance as a second second fluid connection, whereby
the heat storage device exit is fluidically connected to the heat storage device, and the climate control device entrance is fluidically connected to an outlet of the climate control device.

11. The charging station according to claim 10, whereby the two fluid exit connections and the climate control device exit are adapted to one another in such a way that a predetermined distribution of the respective fluid flows, which pass through, is attained during the operation of the charging station.

12. The charging station according to claim 11, comprising a fluid conveying device, which is configured to convey a fluid of the charging station.
